(19) United States
(12) Patent Application Publication
(10) Pub. No.: US 2026/0052935 A1
(43) Pub. Date: Feb. 19, 2026

(54) EDGE RING FOR SELF-MONITORING TEMPERATURE

(71) Applicants: WIT CORPORATION, Hwaseong-si (KR); FINE SEMITECH CORP., Hwaseong-si (KR)

(72) Inventors: Jae Hwan KIM, Hwaseong-si (KR); Kwan Jae LEE, Yongin-si (KR); Jae Won OH, Gunpo-si (KR)

(21) Appl. No.: 19/369,049

(22) Filed: Oct. 24, 2025

Related U.S. Application Data
(63) Continuation of application No. PCT/KR2023/013813, filed on Sep. 14, 2023.

(30) Foreign Application Priority Data
May 17, 2023 (KR) 10-2023-0063832

(51) Int. Cl. H01L 21/67; G01K 1/143; H01L 21/683; H01L 21/687

(52) U.S. Cl. CPC H01L 21/67248; G01K 1/143; H01L 21/6833; H01L 21/68721

(57) ABSTRACT

An edge ring used in a chamber comprises a cover with an internal space, a circuit board disposed in the internal space of the cover and at least one electrical element disposed on the circuit board. Here, the electrical element includes a temperature sensor, and temperature of the edge ring, heat distribution generated when ion bombardment occurs in plasma state or heat flux in the edge ring is measured by using the temperature sensor.

### CROSS-REFERENCE TO RELATED APPLICATIONS

This application is a bypass continuation of pending PCT International Application No. PCT/KR2023/013813, which was filed on Sep. 14, 2023, and which claims priority under 35 U.S.C 119(a) to Korean Patent Application No. 10-2023-0063832 filed with the Korean Intellectual Property Office on May 17, 2023. The disclosures of the above patent applications are incorporated herein by reference in their entirety.

### TECHNICAL FIELD

The present disclosure relates to an edge ring for self-monitoring temperature.

### BACKGROUND ART

An edge ring located next to a ceramic plate of an electrostatic chuck to enhance the process uniformity of a wafer in a semiconductor etching process as shown in FIG. 1.

Generally, the process uniformity of the wafer is deteriorated due to temperature cause, electrical cause, chemical cause, etc.

Referring to the temperature cause, a temperature distribution of a central part of a wafer is different from that of an outermost part of the wafer. In this case, heat is smoothly delivered from a heat source to the central part of the wafer, but it is not easy to deliver smoothly from the heat source to the outermost part of the wafer. In particular, it is more difficult to deliver heat to a side of the wafer because the side of the wafer contacts with vacuum atmosphere in a chamber. To solve this problem, the edge ring is used to compensate temperature of the outermost part of the wafer.

However, the heat is not adequately compensated due to property difference of the wafer and the edge ring, and thus a method of heating indirectly the edge ring by locating a heater between the electrostatic chuck and the edge ring has been used.

In the electrical cause, the electrical feature of the central part of the wafer is different from that of the outermost part of the wafer. The peripheral part of the central part of the wafer has the same property as the central part of the wafer, but the peripheral part of the outermost part of the wafer may have different properties from the outermost part of the wafer because a side of the outermost part is in contact with the vacuum atmosphere. As a result, sheath distribution of plasma of the central part of the wafer is uniform, but sheath distribution of plasma of the outermost part is not uniform.

Accordingly, if ion bombardment is applied to the wafer when plasma generates, a direction of the ion bombardment may be straight at the central part of the wafer but may not be straight at the outermost part of the wafer. As a result, the process uniformity of the wafer may be deteriorated.

To compensate for this electrical feature, a method of adjusting the sheath distribution of the plasma by using the edge is used. In a recent study, a method of adjusting artificially the sheath distribution by inserting an RF power supply to a lower part of the edge ring has been used.

However, the conventional technique tries to artificially enhance the process uniformity of the wafer by using a method of heating the edge ring and so on, but a technique of quantitatively measuring heat does not exist.

### SUMMARY

The present disclosure provides an edge ring for self-monitoring temperature.

An edge ring used in a chamber according to one embodiment of the present disclosure includes a cover with an internal space; a circuit board disposed in the internal space of the cover; and at least one electrical element disposed on the circuit board. In this embodiment, the electrical element includes a temperature sensor configured to measure the temperature of the edge ring, as well as the heat distribution produced by ion bombardment in the plasma state or the heat flux within the edge ring.

An edge ring according to another embodiment of the present disclosure includes a cover configured to have an internal space; a circuit board disposed in the internal space of the cover; at least one electrical element disposed on the circuit board; a first filler configured to cover a lateral surface of the electrical element; and a second filler configured to cover the electrical element or the first filler. Here, the fillers seal the electrical elements.

A chamber according to one embodiment of the present disclosure includes an electrostatic chuck; an edge ring located outside the electrostatic chuck; a first heater located in the electrostatic chuck and configured to apply heat to a wafer to be laid on the electrostatic chuck; a second heater located below the edge ring and configured to apply heat to an outermost part of the wafer. Here, the edge ring includes a cover configured to have an internal space; a circuit board located in the internal space of the cover; and at least one electrical element disposed on the circuit board. The electrical element includes a temperature sensor configured to measure the temperature of the edge ring, as well as the heat distribution produced by ion bombardment in the plasma state or the heat flux within the edge ring.

An edge ring according to one embodiment of the present disclosure includes a self-monitoring temperature function, hereby enabling fine tuning of the heat amount of an electrostatic chuck corresponding to an outermost region of a wafer. As a result, process yield may be improved. As a result, a process yield may be enhanced.

### BRIEF DESCRIPTION OF DRAWINGS

Example embodiments of the present disclosure will become more apparent by describing in detail example embodiments of the present disclosure with reference to the accompanying drawings, in which:

FIG. 1 is a view illustrating a conventional chamber;

FIG. 2 is a view illustrating a chamber according to an embodiment of the present disclosure;

FIG. 3 is a view illustrating the whole shape of an edge ring according to an embodiment of the present disclosure;

FIG. 4 is a sectional view illustrating an edge ring according to an embodiment of the present disclosure;

FIG. 5 is a sectional view illustrating an edge ring according to another embodiment of the present disclosure; and

FIG. 6 and FIG. 7 are views illustrating an edge ring according to still another embodiment of the present disclosure.

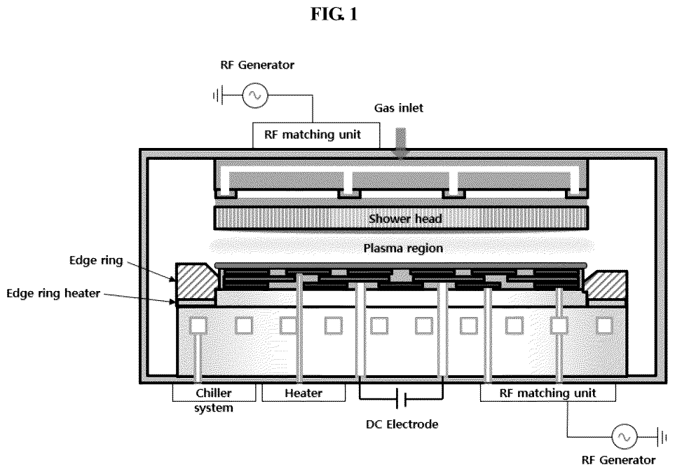

### DETAILED DESCRIPTION

In the present disclosure, an expression used in the singular encompasses the expression of the plural, unless it has a clearly different meaning in the context. In the present specification, terms such as “comprising” or “including,” etc., should not be interpreted as meaning that all of the elements or operations are necessarily included. That is, some of the elements or operations may not be included, while other additional elements or operations may be further included. Also, terms such as “unit,” “module,” etc., as used in the present specification may refer to a part for processing at least one function or action and may be implemented as hardware, software, or a combination of hardware and software.

The present disclosure relates to an edge ring for self-monitoring temperature. The edge ring may self-monitor temperature while retaining functions of the conventional edge ring.

The conventional edge ring does not have a function of quantitatively measuring temperature, and thus it cannot discriminate whether or not heat is normally delivered to an outermost part of a wafer. In contrast, the edge ring of the present disclosure has a function of self-monitoring temperature, and can discriminate whether or not heat is normally delivered to the outermost part of the wafer. The heat may be smoothly delivered to the outermost part of the wafer by adjusting the delivery of the heat when it is not normally delivered to the outermost part. As a result, a process yield of the wafer may be enhanced. For example, the self-monitoring of temperature of the edge and the adjusting of delivery of the heat may be applied to various processes such as an etching process and so on.

Additionally, the conventional technique uses an edge ring to compensate for an electrical feature of a wafer, thereby adjusting sheath distribution. However, the conventional technique does not quantitatively measure the sheath distribution, and thus it cannot discriminate whether or not the electrical feature of the wafer is properly compensated. In contrast, the edge ring of the disclosure may self-monitor temperature and quantitatively measure the sheath distribution of plasma. As a result, the process uniformity of the wafer may be enhanced.

Hereinafter, various embodiments of the present disclosure will be described in detail with reference to accompanying drawings.

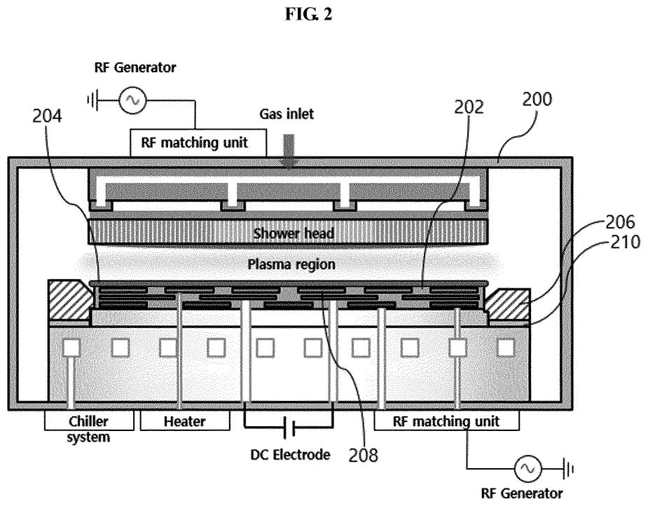

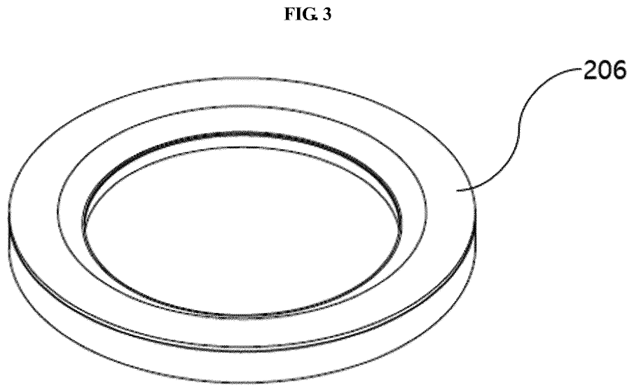

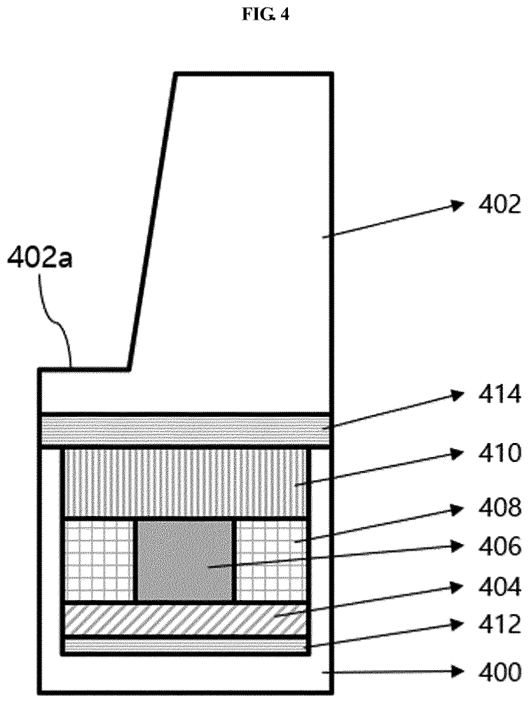

FIG. 2 is a view illustrating a chamber according to an embodiment of the present disclosure, FIG. 3 is a view illustrating the whole shape of an edge ring according to an embodiment of the present disclosure, and FIG. 4 is a sectional view illustrating an edge ring according to an embodiment of the present disclosure.

In FIG. 2, an electrostatic chuck 202 may be located on a lower part of a chamber 200 and a shower head may be located at an upper part of the chamber 200.

A wafer 204 may be disposed on the electrostatic chuck 202, and at least one first heater 208 may be formed in the electrostatic chuck 202. That is, the first heater 208 may heat the wafer 204.

For example, a circular edge ring 206 may be disposed outside the electrostatic chuck 202 as shown in FIG. 3. An external diameter of the wafer 204 is generally higher than that of the electrostatic chuck 202, and thus the edge ring 206 may be disposed outside the electrostatic chuck 202 to control heat of an outermost part of the wafer 204.

A second heater 210 may be disposed below the edge ring 206, and heat of an outermost part of the wafer 204 may be controlled by using heat of the second heater 210 or cooling water located below the wafer 204. In the conventional technique, it is not checked whether the heat of the outermost part of the wafer 204 is normally controlled.

Accordingly, embodiments of the present disclosure provide the edge ring 206 for self-monitoring temperature. That is, the present disclosure may check whether delivery of the heat to the outermost part of the wafer 204 is normally performed by monitoring temperature of the edge ring 206.

In FIG. 4, the edge ring 206 may include a lower cover 400, an upper cover 402, a circuit board 404, an electrical element unit 406, a first filler 408 and a second filler 410.

The lower cover 400 may have ‘E’ shape standing vertically. That is, the lower cover 400 may include a bottom surface and lateral surfaces formed vertically at both ends of the bottom surface, and so an electrical element, etc. may be located in an internal space of the lower cover 400. The lower cover 400 may prevent foreign substances from entering the lower cover 400. Accordingly, structure of the lower cover 400 is not limited as long as the lower cover 400 includes the bottom surface and the lateral surfaces.

In an embodiment of the present disclosure, the lower cover 400 may be manufactured through a laser processing or a wetting etching process, etc. so that it has an internal space wherein the electrical element, etc. is located.

In an embodiment of the present disclosure, the lower cover 400 may be formed of the same material as the wafer 204 or material similar to the wafer 204. For example, the lower cover 400 may be formed of Si or Sic, which is a silicone-based material, or a quartz, which is a glass-based material. This is for smoothly delivering heat from the edge ring 206 to the wafer 204. Of course, the material of the lower cover 400 is not limited to the same material of the wafer 204 or a material similar to the wafer 204.

The upper cover 402 is formed on the lower cover 400, and it may be combined with the lower cover 400 by using an adhesive layer 414 formed of adhesive. However, the combination is not limited to the use of an adhesive, and the combination may be variously modified as long as the upper cover 402 is combined with the lower cover 400.

Here, the adhesive may have a low outgassing feature because it is used in the chamber 200, and a fluorine material with chemical resistance to etching gas may be used as the adhesive. For example, acrylic material or silicone-based material may be used as the adhesive.

The upper cover 402 may be formed of the same material as the wafer 204 or material similar to the wafer 204, e.g. Si or SiC, which is silicone-based material.

In an embodiment of the present disclosure, the upper cover 402 may have a shape similar to the conventional edge ring. That is, a part 402a of a lower surface of the upper cover 402 may be flat compared to an outermost part of the wafer 204, and the other part of the upper cover 402 may be inclined from an end of the part 402a. As a result, the other part of the upper cover 402 except the lower part may have a width smaller than the lower cover 400, and a width of the upper cover 402 becomes narrower in a direction from the lower surface to an upper surface of the upper cover 402.

In another embodiment of the present disclosure, a chemical-resistant material or corrosion-resistant material may be coated on a surface of the upper cover 402. Here, the coated material may be ceramic material such as YOF, Al2O3, Y2O3, YAQ etc. or a CH-based polymer. On the other hand, this coating may be also performed on a surface of the lower cover 400.

The circuit board 404 may be disposed in the internal space of the lower cover 400.

In an embodiment of the present disclosure, the circuit board 404 may be combined with a bottom surface of the lower cover 400 through an adhesive of an adhesive layer 412. Here, the adhesive may have a low outgassing feature, and fluorine material with chemical resistance to etching gas may be used as the adhesive. For example, an acrylic material or silicone-based material may be used as the adhesive.

Thickness of the circuit board 404 may differ according to the thickness of the edge ring 206.

The electrical element unit 406 may be located on the circuit board 404 in an internal space of the lower cover 400 and it may include at least one electrical element.

For example, the electrical element unit 405 includes a temperature sensor for measuring temperature distribution of the lower cover 400, and it may further include one or more of a microprocessor, a wireless communication module, a wireless charging module, a wireless power supply, a semi-solid-state or all-solid-state battery and a memory.

In an embodiment of the present disclosure, the electrical elements may be sealed. Specifically, the electrical elements may be sealed by a first filler 408 and a second filler 410 as shown in FIG. 4. Here, an upper surface of the second filler 410 may be flat and an adhesive layer 414 may be disposed on the second filler 410.

The first filler 408 may cover lateral surfaces of the electrical elements in the electrical element unit 406 or the lateral surfaces and at least part of an upper surface of the electrical elements on the circuit board 404. The first filler 408 may make the electrical elements have the same height. For example, the first filler 408 may cover the other electrical elements based on the highest electrical element of the electrical elements so that the height of the other electrical elements covered by the first filler 408 is identical to that of the highest electrical element. As a result, the first filler 408 may be used on the other electrical elements except the highest electrical element, thereby making all of the electrical elements have the same height.

The first filler 408 may be solid or liquid.

Si or SiC, which is silicone-based material, PEEK, glass, ceramic material, quartz, etc. may be used as the first filler 408 when the first filler 408 is solid, wherein the thermal expansive coefficient of PEEK, glass, ceramic material or quartz is similar to that of Si or SiC. This is to maximizing sensitivity of the temperature sensor in view of heat conductivity or heat flux when the temperature is measured. Of course, the first filler 408 is not limited to the above material.

On the other hand, the first filler 408 may be combined with the circuit board 404 by using the adhesive mentioned above when the first filler 408 is solid.

Cured resin, e.g. epoxy or silicone-based material, may be used as the first filler 408 when the first filler 408 is liquid. To form the first filler 408 with liquid is to compensate for the step difference of the electrical elements and ensure flatness of the electrical elements when the electrical elements on the circuit board 404 have different heights. For example, the first filler 408 on the electrical elements may be flat by applying a polishing process after filling the first filler 408 on the electrical elements.

On the other hand, material with a low heat shrinkage rate may be used as the first filler 408 if hardness of the first filler 408 is more than 80 D when the first filler 408 is liquid.

The second filler 410 may be disposed between a height corresponding to a height of the highest electrical element and a height of the lower cover 400 and be solid or liquid. As a result, the height of an upper part of the lower cover 400 may be identical to that of the second filler 410.

The second filler 410 may be formed of the same material as the first filler 408 or material similar to the first filler 408.

On the other hand, one filler may cover the electrical elements in an internal space of the lower cover 400.

Briefly, the edge ring 206 of the present embodiment may self-measure temperature by disposing the electrical elements such as the temperature sensor, etc. in the internal space of the lower cover 400 with performing the conventional edge ring. As a result, the edge ring 206 may detect temperature characteristics of the heater 210 located below the edge ring 206 based on the measured temperature. The heating amount of the electrostatic chuck 202 or the heater 210 corresponding to the outermost part of the wafer 204 may be finetuned by using the detected result, thereby enhancing process yield.

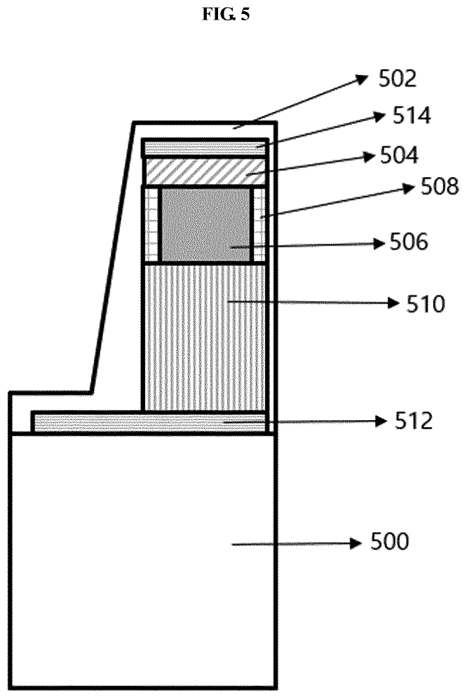

FIG. 5 is a sectional view illustrating an edge ring according to another embodiment of the disclosure.

In FIG. 5, the edge ring 206 of the present embodiment may include a lower cover 500, an upper cover 502, a circuit board 504, an electrical element unit 506, a first filler 508, a second filler 510, a first adhesive layer 512 and a second adhesive layer 514.

Unlike the embodiment in FIG. 4, the electrical elements may be located in an internal space of the upper cover 502 not the lower cover 500.

The lower cover 500 may be combined with the upper cover 502 by using the first adhesive layer 512. However, the combination may not be limited to the method of using an adhesive of the first adhesive layer 512 and be variously modified as long as the lower cover 500 is combined with the upper cover 512.

The adhesive may be identical to or similar to the adhesive in FIG. 3.

The second filler 510 may be formed on the first adhesive layer 512 in the internal space of the upper cover 502. The second filler 510 may have the same material as the second filler 410 in FIG. 3 or material similar to the second filler 410.

The electrical elements of the electrical element unit 506 may be disposed on the second filler 510 in the internal space of the upper cover 502. Here, the electrical elements include a temperature sensor, etc.

The first filler 508 may cover a lateral surface and an upper surface of the electrical elements so that the electrical elements have the same height. Here, the first filler 508 may have the same material as the first filler 408 in FIG. 3 or material similar to the first filler 408.

The circuit board 504 may be disposed on the electrical elements, and the circuit board 504 may be combined with an internal surface of the upper cover 502 through the second adhesive layer 514. Of course, the combination is not limited to a method of using the adhesive and may be variously modified.

The adhesive may be formed of the same material as the adhesive in FIG. 3 or material similar to the adhesive in FIG. 3.

Referring to the disposition of elements in the upper cover 502 based on the upper surface of the upper cover 502, electrical elements may be disposed on the circuit board 504 and the fillers 508 and 510 may seal the electrical elements.

Shortly, in the edge ring 206 of the present embodiment, the circuit board 504 and the electrical elements may be disposed in the upper cover 502. As a result, the temperature sensor is located at an upper part of the edge ring 206. In this case, the edge ring 206 may measure distribution of heat generated when ion bombardment is applied to the wafer 204 in plasma state of the chamber 200, along with self-measuring the temperature.

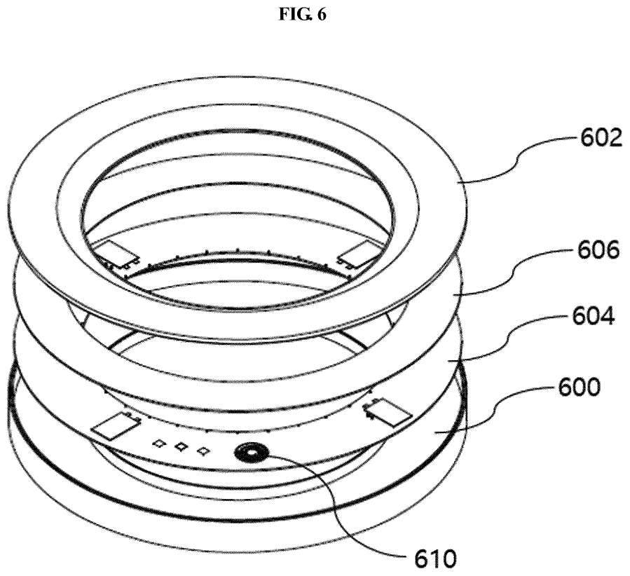

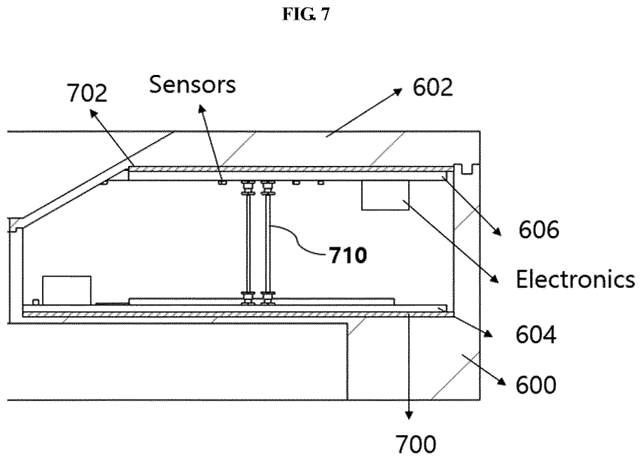

FIG. 6 and FIG. 7 are views illustrating an edge ring according to still another embodiment of the present disclosure.

In FIG. 6, the edge ring 206 of the present embodiment may include a lower cover 600, an upper cover 602, a first circuit board 604, a second circuit board 606, first electrical elements and second electrical elements. That is, the edge ring 206 of the present embodiment is a merged structure of the edge ring 206 in FIG. 4 and the edge ring 206 in FIG. 5. In the edge 206 of the present embodiment, the first circuit board 604 and related electrical elements are located in an internal space of the lower cover 600, and the second circuit board 606 and related electrical elements are disposed in an internal space of the upper cover 602. Elements may be formed of the same material as in above embodiments or material similar to those in above embodiments.

The lower cover 600 and the upper cover 602 may be combined by using an adhesive or groove and a projection member. That is, the combination may be variously modified as long as the covers 600 and 602 are combined.

Additionally, ceramic material or polymer-based material may be coated on the upper cover 602 to prevent a surface of the upper cover 602 from being etched when an etching process is performed. Here, the coating may be performed on the lower cover 600 or may not be performed on the lower cover 600.

The first electrical elements may be formed on the first circuit board 604 and be sealed by fillers. A first temperature sensor of the first electrical elements measures temperature distribution of the lower cover 600. The first electrical elements may further include a battery, a microprocessor and so on.

In an embodiment of the present disclosure, an RF coil 610 may be formed on the first circuit board 604 as shown in FIG. 6. The RF coil 610 may function as a transceiver for wireless communication or a reception unit for wireless charging.

In an embodiment of the present disclosure, the first circuit board 604 may be electrically connected to the second circuit board 606 through at least one connector 710 as shown in FIG. 7. As a result, power may be supplied to the other circuit board if a power supply or a battery exists on one of the circuit boards 604 and 606. The function in FIG. 7 may be achieved by applying a wireless communication method to a merged structure of a lower cover part in FIG. 4 and an upper cover part in FIG. 5, which is not shown in FIG. 6.

Fillers for sealing electrical elements may be filled in the lower cover 600 and the upper cover 602, which is not shown in FIG. 6.

In another embodiment of the present disclosure, a filler for sealing the first electrical elements and a filler for sealing the second electrical elements do not exist independently, but a space between the circuit boards 604 and 606 is formed and a filler is filled in the space as shown in FIG. 7. Here, the filler may be formed of material with high heat conductivity.

Silicone, epoxy or material with a low outgassing feature may be used as the filler when or rigidity of the filler is more than 80 D.

In still another embodiment of the present disclosure, a first EMI shielding layer 700 for protecting electrical elements from electromagnetic wave of plasma may exist between the lower cover 600 and the first circuit board 604, and a second EMI shielding layer 702 may exist between the upper cover 602 and the second circuit board 606.

On the other hand, adhesive layers for adhering the covers 600 and 602 to the circuit boards 604 and 606 do not exist, but the EMI shielding layers 700 and 702 may perform an adhering function as well as a shielding function of electromagnetic wave.

In brief, the edge ring 206 of the present embodiment includes a temperature sensor located at its upper part and a temperature sensor located at its lower part. In this case, the edge ring 206 may measure heat flux from the upper part to the lower part or heat flux from the lower part to the upper part as well as temperature distribution of the covers 600 and 602.

The heating amount of the electrostatic chuck 202 corresponding to the outermost part of the wafer 204 may be finetuned if the edge ring 206 measures the temperature distribution or the heat flux. That is, heat may be uniformly applied to the wafer 204 by adjusting heaters 208 for heating the electrostatic chuck 202 and the heater 210 below the edge ring 206. As a result, the process yield of the wafer 204 may be enhanced.

The upper cover and the lower cover exist independently in above embodiments, but the upper cover and the lower cover may be integrally formed.

Components in the embodiments described above can be easily understood from the perspective of processes. That is, each component can also be understood as an individual process. Likewise, processes in the embodiments described above can be easily understood from the perspective of components.

The embodiments of the present disclosure described above are disclosed only for illustrative purposes. A person having ordinary skill in the art would be able to make various modifications, alterations, and additions without departing from the spirit and scope of the disclosure, but it is to be appreciated that such modifications, alterations, and additions are encompassed by the scope of claims set forth below.

1. An edge ring used in a chamber comprising:
a cover with an internal space;
a circuit board disposed in the internal space of the cover; and
at least one electrical element disposed on the circuit board,
wherein the electrical element includes a temperature sensor, and
wherein the temperature sensor measures temperature of the edge ring, heat distribution generated when ion bombardment occurs in plasma state or heat flux in the edge ring.

2. The edge ring of claim 1, wherein the cover includes an upper cover and a lower cover combined each other,
and wherein the lower cover has the internal space, the circuit board and the electrical element are sequentially disposed on a bottom surface of the lower cover in the internal space,
the circuit board and the lower cover are combined by using a first adhesive, the lower cover and the upper cover are combined by using a second adhesive,
a first filler covers a lateral surface or at least part of an upper surface of the electrical element on the circuit board, a second filler is disposed on the electrical element and the first filler, and
the temperature sensor measures temperature distribution of the lower cover.

3. The edge ring of claim 2, wherein the first filler is filled on an electrical element smaller than the highest electrical element of the electrical elements based on the highest electrical element, and
the electrical elements are sealed by the first filler and the second filler.

4. The edge ring of claim 1, further comprising:
a filler configured to seal the electrical element by covering the electrical element in the internal space,
wherein silicone-based material, PEEK, glass, ceramic material or quartz is used as the filler when the filler is solid.

5. The edge ring of claim 1, further comprising:
a filler configured to seal the electrical element in the internal space,
wherein epoxy or silicone-based material is used as the filler when the filler is liquid.

6. The edge ring of claim 1, wherein the cover is formed of Si or SiC which is silicone-based material or quartz which is glass-based material.

7. The edge ring of claim 1, wherein the cover includes an upper cover and a lower cover combined each other,
and wherein the upper cover has the internal space, the circuit board and the electrical element are sequentially disposed on a bottom surface of the upper cover in the internal space,
the circuit board is combined with the upper cover through a first adhesive, the lower cover is combined with the upper cover through a second adhesive,
a first filler covers a lateral side and at least part of an upper surface of the electrical element on the circuit board, a second filler is formed on the electrical element and the first filler, and
the temperature sensor measures temperature distribution of the upper cover or distribution of heat generated when the ion bombardment occurs.

8. The edge ring of claim 1, wherein the cover includes an upper cover and a lower cover combined each other by using an adhesive,
and wherein acrylic material or silicone-based material is used as the adhesive.

9. The edge ring of claim 1, wherein the circuit board includes a first circuit board and a second circuit board, and the electrical element includes a first electrical element and a second electrical element,
and wherein the first electrical element locates on the first circuit board at a lower part of an internal space of the cover, the second electrical element is disposed on the second circuit board at an upper part of the internal space,
a filler seals the electrical elements in the internal space,
the first electrical element includes a first temperature sensor, the second electrical element includes a second temperature sensor, and
heat flux in the internal space is measured through temperature sensed by the temperature sensors.

10. The edge ring of claim 9, wherein the first circuit board and the second circuit board are electrically connected through at least one connector.

11. The edge ring of claim 9, wherein a first EMI shielding layer locates between the first circuit board and a bottom surface of the cover, and a second EMI shielding layer is disposed between the second circuit board and an upper surface of the cover.

12. An edge ring comprising:
a cover configured to have an internal space;
a circuit board disposed in the internal space of the cover;
at least one electrical element disposed on the circuit board;
a first filler configured to cover a lateral surface of the electrical element; and
a second filler configured to cover the electrical element or the first filler,
wherein the first and second fillers seal the electrical elements.

13. The edge ring of claim 12, wherein the first filler covers the lateral surface and at least part of an upper part of the electrical element and covers an electrical element lower than the highest electrical element.

14. A chamber comprising:
an electrostatic chuck;
an edge ring located outside the electrostatic chuck;
a first heater located in the electrostatic chuck and configured to apply heat to a wafer to be laid on the electrostatic chuck;
a second heater located below the edge ring and configured to apply heat to an outermost part of the wafer,
wherein the edge ring includes
a cover configured to have an internal space;
a circuit board located in the internal space of the cover; and
at least one electrical element disposed on the circuit board,
and wherein the electrical element includes a temperature sensor, and the temperature sensor measures temperature of the edge, distribution of heat generated when ion bombardment occurs in plasma state or heat flux in the edge ring.

15. The chamber of claim 14, wherein the first heater or the second heater is controlled based on temperature measured by the temperature sensor so that heat applied to the wafer is adjusted.
